(19) United States
(12) Patent Application Publication
(10) Pub. No.: US 2023/0316115 A1
(43) Pub. Date: Oct. 5, 2023

(54) AUTOMATIC ESTIMATION OF PHYSICS PARAMETERS IN A DIGITAL TWIN SIMULATION

(71) Applicant: Siemens Aktiengesellschaft, Munich (DE)

(72) Inventors: Juan L. Aparicio Ojea, Moraga, CA (US); Heiko Claussen, Wayland, MA (US); Ines Ugalde Diaz, Redwood City, CA (US); Martin Sehr, Kensington, CA (US); Eugen Solowjow, Berkeley, CA (US); Chengtao Wen, Redwood City, CA (US); Wei Xi Xia, Daly City, CA (US); Xiaowen Yu, Union City, CA (US); Shashank Tamaskar, Mohali, Punjab (IN)

(73) Assignee: Siemens Aktiengesellschaft, Munich (DE)

(21) Appl. No.: 18/041,824

(22) PCT Filed: Aug. 28, 2020
(86) PCT No.: PCT/US2020/048320

§ 371 Date: Feb. 16, 2023

(51) Int. Cl. G06N 7/01; G06F 30/20

(52) U.S. Cl. CPC G06N 7/01; G06F 30/20

(57) ABSTRACT

A computer-implemented method includes operating a controllable physical device to perform a task. The method also includes miming forward simulations of the task by a physics engine based on one or more physics parameters. The physics engine communicates with a parameter data layer where each of the one or more physics parameters is modeled with a probability distribution. For each forward simulation run, a tuple of parameter values is sampled from the probability distribution of the one or more physics parameters and fed to the physics engine. The method includes obtaining an observation pertaining to the task from the physical environment and a corresponding forward simulation outcome associated with each sampled tuple of parameter values. The method then includes updating the probability distribution of the one or more physics parameters in the parameter data layer based on the observation from the physical environment and the corresponding forward simulation outcomes.

### TECHNICAL FIELD

The present disclosure relates generally to the field of digital twin simulation. Described embodiments are directed to a technique for automatic tuning of physics parameters in a digital twin simulation.

### BACKGROUND

Simulation technologies may be used, for example, for predicting behavior of real world objects or for explaining behavior of past events. An exemplary application of simulation technology is in digital twins.

The next generation of engineering tools for autonomous systems will embed a digital twin of the real world. Autonomy typically gives each asset on the factory floor the decision-making and self-controlling abilities to act independently in the event of local issues. One of the purposes of the digital twin will be to serve as a belief representation to the autonomous system. The autonomous system can use this representation of the world to reason about its actions and their effects on the world. A physics engine (e.g. Bullet™, Mujoco™, among others) is at the core of this digital twin representation of the world.

One of the challenges associated with a digital twin simulation is a discrepancy between an observed output in the real world and a corresponding output for the same experiment carried out by simulation. Often, this discrepancy arises due to inaccuracies in the parameters used in the physics engine.

In robotics simulations, physics parameters (e.g., friction) are manually set and tuned. The determination of appropriate physics parameters remains a tedious task, which often requires substantial domain knowledge. Due to its complexity, the task of setting detailed physics parameters such as friction forces is generally only roughly estimated or avoided. Many common approaches only visualize or simulate collision boundaries and thus limit the range of use cases. Alternatively, custom policies are hand crafted by roboticists (e.g., spiral search for a peg in hole problem) to avoid friction dependent programming. If exact friction forces are required, automated exploratory approaches in the real world can be applied that implicitly include the model parameter in the found policy to solve a problem at hand (e.g., using reinforcement learning).

### SUMMARY

Briefly, aspects of the present disclosure pertain to a technique for automatic estimation of physics parameters in a digital twin simulation.

A first aspect of the disclosure sets forth a computer-implemented method. The method comprises operating a controllable physical device to perform a task in a physical environment. The method also comprises running forward simulations of the task by a physics engine based on one or more physics parameters. The physics engine communicates with a parameter data layer in which each of the one or more physics parameters is represented as a probabilistic variable with an associated probability distribution. For each forward simulation run, a tuple of parameter values is sampled from the probability distribution of the one or more physics parameters and fed to the physics engine. The method comprises obtaining an observation pertaining to the task from the physical environment and a corresponding forward simulation outcome associated with each sampled tuple of parameter values. The method then comprises updating the probability distribution of the one or more physics parameters in the parameter data layer based on the observation from the physical environment and the corresponding forward simulation outcomes.

Other aspects of the present disclosure implement features of the above-described method in computing systems and computer program products.

Additional technical features and benefits may be realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The foregoing and other aspects of the present disclosure are best understood from the following detailed description when read in connection with the accompanying drawings. To easily identify the discussion of any element or act, the most significant digit or digits in a reference number refer to the figure number in which the element or act is first introduced.

FIG. 1 illustrates an autonomous system according to an example embodiment.

FIG. 2 schematically illustrates a parameter data layer for synchronizing parameters of a physics engine with real world observations.

FIG. 3 is a flowchart illustrating a particle filter based method for recursively updating parameter probability distribution according an example method.

FIG. 4 is a flowchart illustrating the use of active learning to design a task according to an example embodiment.

FIG. 5 illustrates a computing system in accordance with an aspect of the disclosure.

### DETAILED DESCRIPTION

Various technologies that pertain to systems and methods will now be described with reference to the drawings, where like reference numerals represent like elements throughout. The drawings discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged apparatus. It is to be understood that functionality that is described as being carried out by certain system elements may be performed by multiple elements. Similarly, for instance, an element may be configured to perform functionality that is described as being carried out by multiple elements. The numerous innovative teachings of the present application will be described with reference to exemplary non-limiting embodiments.

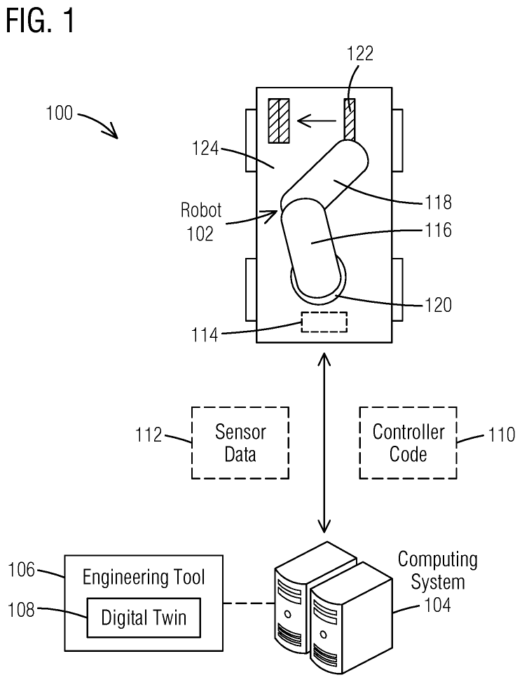

Referring to FIG. 1, an autonomous system 100 according to the described embodiment comprises a physical device, such as a robot 102, which is controllable by a computer or computing system 104 to carry out a task in a physical environment. The computing system 104 may comprise, for example, an industrial PC, or any other computing device, such as a desktop or a laptop, among others, which may be configured to execute an application program for operating the robot 102. In the described embodiment, the application program is embodied in an engineering tool 106.

To realize autonomy of the system 100, the engineering tool 106 may be designed to operate the robot 102 to perform a task in a skill-based programming environment. In contrast to conventional automation, where an engineer is usually involved in programming an entire task from start to finish, typically utilizing low-level code to generate individual commands, in an autonomous system as described herein, a physical device, such as the robot 102, is programmed at a higher level of abstraction using skills instead of individual commands. The skills are derived for higher-level abstract behaviors centered on how the physical environment is to be modified by the programmed physical device. Illustrative examples of skills include a skill to grasp or pick up an object, a skill to place an object, a skill to open a door, a skill to detect an object, and so on.

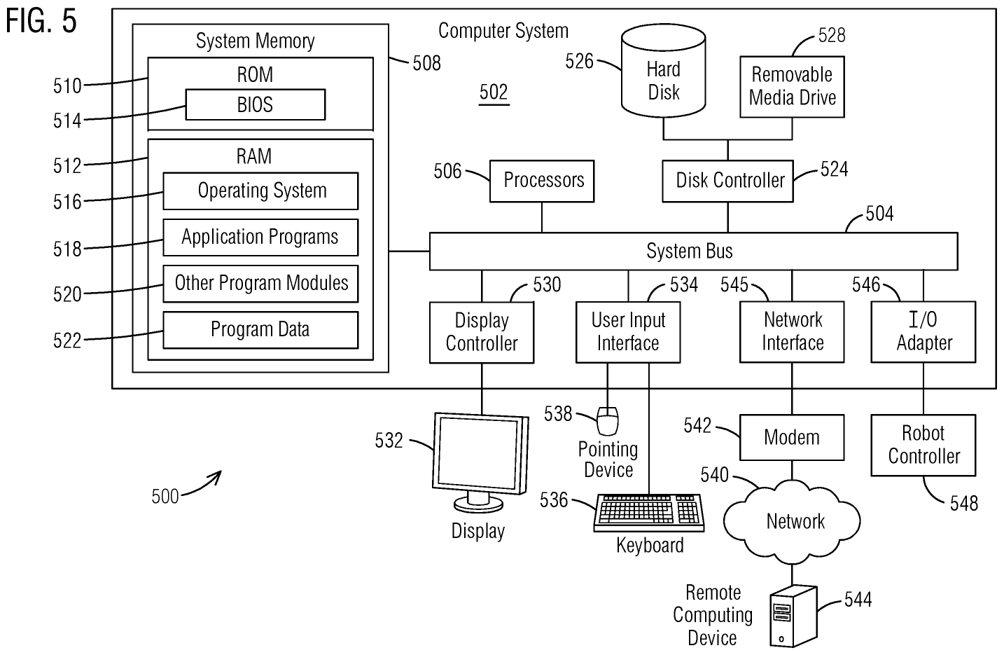

The engineering tool 106 may generate controller code 110 that defines a task at a high-level using skill functions, which may be deployed to a robot controller 114. From the high-level controller code 110, the robot controller 114 may generate low-level control signals for one or more motors for controlling the movement of the robot 102, such as angular position of the robot arms 116, 118, swivel angle of the robot base 120, and so on, to execute the specified task. In some embodiments, the controller code 110 generated by the engineering tool 106 may be deployed to intermediate control equipment, such as programmable logic controllers (PLC), which may then generate low-level control commands for the physical device to be controlled. Additionally, the engineering tool 106 may be configured to directly integrate sensor data 112 from the physical environment in which the robot 102 operates. To this end, the computing system 104 may comprise a network interface to facilitate transfer of live data between the engineering tool 106 and the physical environment. An example of a computing system suitable for the present application is described hereinafter in connection with FIG. 5.

Continuing with reference to FIG. 1, embedded in the engineering tool 106 is a digital twin 108 of the real world, which may be used to obtain a digital representation of a state of the physical environment in which the robot 102 operates. The digital twin 108 may comprise a high-fidelity model of the real-world, which may utilize, for example, CAD models representing physical objects in the operating environment of the robot 102 (including the robot 102 itself). In other embodiments, instead of or in addition to employing CAD models, sensor data, such as imaging data, may be utilized to generate digital representations of the physical objects. The digital twin 108 further includes a physics engine configured to execute a simulation of the physical environment for a task being carried out or to be carried out by the robot 102.

One of the purposes of the digital twin 108 is to serve as a belief representation to the autonomous system 100. The autonomous system 100 can use this representation of the world to reason about the actions of the robot 102 and their effects on the world. The physics engine captures the main physical relationships between objects in the physical environment and can enable both co-simulation and forward simulations. Co-simulation refers to a simulation of the real world executed in parallel as the robot 102 executes a physical task. Ideally, a co-simulation should reflect the exact state of the real world (physical environment of the robot 102) at any given instant. The autonomous system 100 may query the co-simulation from time to time, for example, to obtain information about things that cannot be measured or observed directly from the physical environment. A forward simulation refers to a forecasting of the dynamics of the physical environment consequent to a task or action to be executed by the robot 102, starting from a given world state.

Trying out actions in the belief space is convenient for finding the right action to apply it in the real world. For example, as shown in FIG. 1, the autonomous system 100 can use forward simulations to evaluate which force would be required to push an object 122 on a table 124 for the object 122 to reach a desired position (for e.g., to be arranged next to the other objects on the table). In this example, the relevant physics effects are rigid body motion, contact dynamics and friction. Many physical relationships can be captured well by first order modelling up to certain coefficients and parameters. For example, although Coulomb's law describes friction forces, a friction coefficient needs to be specified, which depends, amongst other factors, on the material pairing. In order for the described skill-based engineering tool 106 to be useful, it is desirable to capture not only the physical laws well enough, but also set all physical parameters according to the situation in which the autonomous system is acting. Inaccuracies in the parameter values may lead to discrepancies between simulation and the real world.

Aspects of the present disclosure enable a digital twin simulation to automatically synchronize its underlying physical models, and in particular, the physics parameters, to closely match the real world. This is achieved by introducing a parameter data layer, which explicitly models the physics parameters as probabilistic variables and updates them based on observations from the real world.

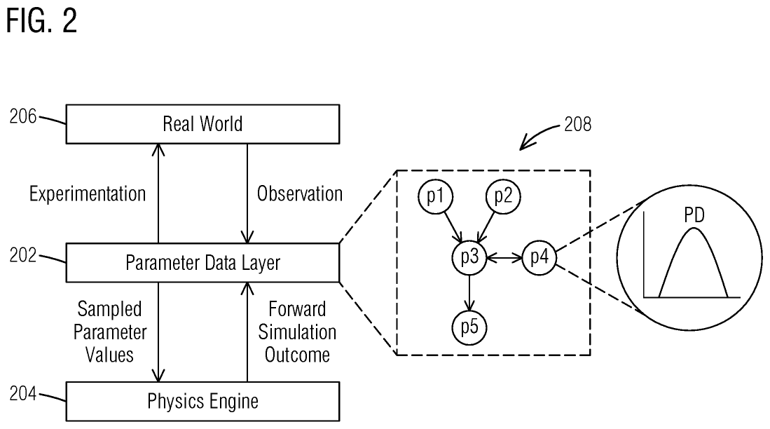

Referring to FIG. 2, the parameter data layer 202 contains information on one or more relevant physics parameters. The purpose of the parameter data layer 202 is to estimate the physics parameters so that the simulated world resembles the real world. Unlike within the physics engine 204 which uses a specific value for each physics parameter, each physics parameter in the parameter data layer 202 is represented as a probabilistic variable with an associated probability distribution. For performing co-simulation, the physics engine 204 may use the means (averages) of these probability distributions as parameter values. If the probability distributions of the physics parameters change based on observations from the physical environment (or real world “206”), then the parameter values are updated in the physics engine 204 for co-simulation (e.g., using mean values of the updated distributions).

The relevant physics parameters typically comprise one or more parameters that cannot be directly observed or measured from the real world 206 but which are correlated to physical effects that may be directly observed or measured. An example of such a parameter is coefficient of friction. Referring back to FIG. 1, the coefficient of friction between the table 124 and the object 122 cannot be measured directly. However, what is observed is a physical effect, namely, the distance that the object 122 slides on the table 124 in a given time interval with a known force being applied by the robot arm 118. The simulation framework provides an input-output model that is parametrized by the physics parameters. The input for this example would be the applied force and the output would be the motion of the object while the friction would be the parameter of interest. The parameter of interest is estimated indirectly through the evolution of a dynamical system. For such a parameter, the “observations” thus pertain to the measurement of a physical effect correlated to the parameter and not a direct measurement of the parameter itself.

In order to be useful for autonomous systems, an engineering tool needs to be able to capture complex environments. Hence, often, several physics parameters need to be considered at the same time. Moreover, the physics parameters can be correlated to and dependent on each other, and as such, can also have a hierarchical order. For example, the mass of a rigid body is correlated with its tensor of inertia, with the latter being dependent (hence hierarchically lower) than the former. In the illustrated embodiment, a plurality of physics parameters are modeled as a probabilistic graphical model (PGM) 208 in the parameter data layer 202. PGMs relate probabilistic variables to each other. An example of a probabilistic graphical model suitable for the present application is a dynamic Bayesian network. The underlying PGM of the presently described engineering tool contains all relevant physics parameters represented through probability distributions. These parameters are used in the physical equations of the physics engine. Real world data changes the distribution to reflect which of the parameter values are more likely and which are less likely.

As shown in FIG. 2, each node p1, p2, p3, p4, p5 in the PGM 208 indicates a physics parameter and the directed edges describe a conditional dependence between the parameters. Each node or parameter in the PGM 208 is associated with a probability distribution PD that reflects an uncertainty associated with that parameter. The probability distribution associated with a node in the PGM 208 is conditionally dependent on its parent node(s). The probability distribution PD associated with each node/parameter typically includes a Gaussian function, although the probability distribution may be described by other functions, such as a mixture of Gaussians, or even a non-Gaussian function.

Prior to collecting real world data, all parameters are represented by an initial probability distribution which is gradually adapted by subsequent observations. The initial probability distribution may be modeled, for example, based on domain-specific knowledge. The state-of-the-art physics engines already work with user-specified parameter values. In an example embodiment, the initial probability distribution in the parameter data layer 202 may be defined by modeling a Gaussian distribution around existing user-specified values for these parameters, which are used as the mean values for the respective Gaussian distributions. This approach provides a simple means to upgrade an existing physics simulation tool by plugging in a parameter data layer representing the physics parameters by probability distributions, to take into account uncertainties around the existing user-specified parameter values. The variance of the initial Gaussian distribution may be set, again, based on domain knowledge, or a rule of thumb. The initial variance setting is not critically important as the proposed parameter estimation process described below would converge from any variance to the right result.

The parameter estimation process may be executed automatically in the background as the robot is operated to perform a task or experiment. The parameter estimation process involves running forward simulations of the specified task by the physics engine 204 based on the relevant physics parameters. For each forward simulation run, a tuple of parameter values is sampled from the probability distributions of the physics parameters in the parameter data layer 202 and fed to the physics engine 204. Each sample or tuple thus represents one possible hypothesis of parameter values. Typically, this results in a large number of forward simulations since the number of possible hypotheses may be very high, at least initially, when the uncertainties associated with the physics parameters is higher. The physics engine 204 runs forward simulations for each sample and returns a simulation outcome associated with each forward simulation run. Each forward simulation outcome predicts a state or physical effect in the real world at a defined time step in the future. At the defined time step, an actual observation pertaining to the task or experiment is then obtained from the real world 206 (e.g., based on sensor data), which corresponds to the state or physical effect predicted by the forward simulation runs. The observation may be also modeled as a probability distribution (typically Gaussian) around a measured value, to reflect noise associated with sensor measurements. The probability distribution of the physics parameters in the parameter data layer 202 is then updated based on the observation from the real world 206 and the corresponding forward simulation outcomes. In particular, each forward simulation outcome may be compared with the observation from the real world to determine, for each sample (tuple of parameter values), the probability that said sample would produce that observation, using Bayesian inference. The probability distributions of the parameters may then be updated based on the comparisons. A Bayesian approach reflects the uncertainty about parameters, because it provides a probability distribution and not just the most likely values. This helps to decide on the confidence about the parameters.

The parameter estimation process typically involves recursively performing the above-described steps over a series of discrete time steps as the robot is carrying out the assigned task based on a Bayesian filter. Herein, the updated probability distributions of the physics parameters for a particular time step are utilized for sampling parameter values that are fed to the physics engine 204 for running forward simulations for the next time step. Non-limiting examples of Bayesian filters include particle filter, Kalman filter, among many others. The choice of the Bayesian filter may be specific to the application. For example, a Kalman filter is suitable for purely Gaussian probability functions, while a particle filter relaxes that requirement and is particularly effective in case of a low-dimensional parameter space.

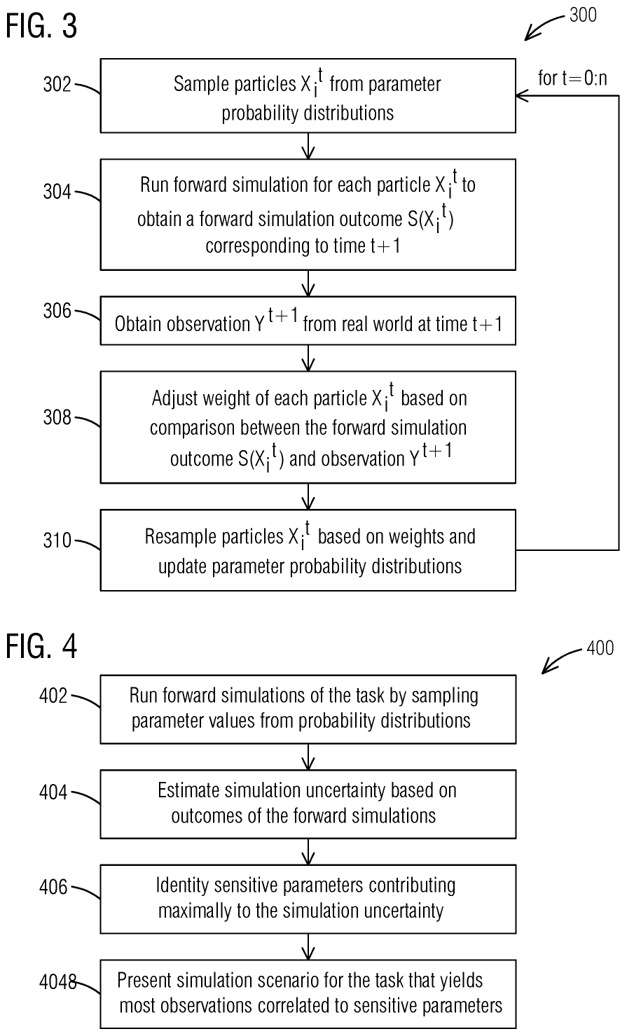

FIG. 3 is a flowchart illustrating a recursive parameter estimation process 400 using a particle filter based algorithm. A particle filter is an evolution-type algorithm where each sampled tuple of parameter values is represented as a particle. The particle filter reinforces those particles whose forward simulation outcomes are closest to the observation from the real world in preference to those particles whose forward simulation outcomes are farther from the observation from the real world. After some iterations, the parameter distribution remains that best synchronizes the simulation with the real world.

The process 300 may be executed in a computing environment simultaneously as a physical device, such as a robot, performs a task or experiment in a physical environment. Block 302 of the process involves sampling particles Xᵢ^{t} from the probability distributions of the physics parameters in the parameter data layer using a Monte Carlo technique. Each particle Xᵢ^{t} represents a tuple of parameter values sampled at time step t. If the initial probability distributions associated with the physics parameters at t=0 are continuous probability distributions, the particles Xᵢ⁰ are sampled by first discretizing the continuous probability distributions associated with the parameters. Block 304 involves feeding the sampled particles Xᵢ^{t} to a physics engine to run a forward simulation for each particle Xᵢ^{t}. Thereby, for each particle Xᵢ^{t}, a forward simulation outcome S(Xᵢ^{t}) is obtained, which predicts a state or physical effect in the real world at the next time step t+1. Block 306 involves obtaining an observation Y^{t+1} from the real world at the next time step t+1. The observation Y^{t+1} corresponds to the state or physical effect predicted by the forward simulation runs. The observation Y^{t+1} is modeled as a probability distribution (typically Gaussian) around a measured value, to reflect noise associated with sensor measurements. Block 308 involves assigning or adjusting a weight of each particle Xᵢ^{t} based on a comparison between the forward simulation outcome S(Xᵢ^{t}) and observation Y^{t+1}. For each particle Xᵢ^{t}, Bayesian inference may be used to determine the probability that the particle Xᵢ^{t} produced the observation Y^{t+1}. Particles Xᵢ^{t} which have a higher probability of producing the observation Y^{t+}are assigned a higher weight in comparison to particles Xᵢ^{t} which have a lower probability of producing the observation Y^{t+1}. Block 310 involves resampling the particles Xᵢ^{t} based on the weights assigned at block 308 and updating parameter probability distributions. In the resampling step, particles associated with a significant weight are replicated, while particles associated with an insignificant weight are removed. This ensures that the particles that reflect the real world behavior survive and are reinforced while particles which do not reflect the reality die out. The process is then repeated for the next time step and carried out iteratively for n defined time steps.

As the physics parameters are estimated and their probability distributions are updated, the physics engine 206 may carry out co-simulations of the task on the digital twin based on a mean value of each of the physics parameters, which is obtained from the updated probability distributions at each time step. As the iterations continue, the uncertainty associated with the parameter probability distributions decrease, thus enabling the co-simulation to closely match the reality. The probabilistic representation of the parameters in the parameter data layer also enables prediction of an uncertainty or confidence associated with the co-simulation of a physical task based on a variance in the current probability distribution of the parameters in the parameter data layer. An additional benefit of representing physics parameters as probabilistic variables (even when they can be directly measured) is that the probabilistic model is sensitive to a change in value of the parameter caused by the dynamics of the physical system. For example, the mass of an object may decrease if a part of the object was broken or chipped off in the real world. In such a case, if mass is modeled as a probabilistic variable, the updated probability distribution of mass would gain uncertainty to reflect that change in the real world.

The above-described embodiments of the parameter estimation process may be executed either actively or passively. In a passive execution, the computing system gathers whatever data from the real world is obtained by the actions of the robot. In contrast, in an active execution, the computing system may direct the robot on how to perform a task or experiment to yield maximum information on parameters of interest. This may be based on an active learning algorithm. Active learning algorithms are machine learning techniques that can query an information source to label some data points. In the present case, the simulation environment may use sensitivity analysis and present a simulation scenario whose execution in the real world would result in the highest information content for estimating the parameter of interest. A robot can then execute a motion on the basis of which real world data can be collected.

As an illustrative example, each unknown object in a workspace of interest may be initialized with a mass according to its observed volume, e.g., measured by a 3D point cloud camera observing the scene. Rather than assigning one fixed value, the mass may be represented by a distribution representing the most likely materials e.g., plastics, wood, metals etc. Similarly, different physical parameters of interest can be initialized, such as the friction coefficient, thermal coefficient, conductive properties etc. Most of these properties will not be of interest to the task at hand and this initialization can thus be triggered ad-hoc based on the first demand of the use cases. Also, many applications will not require the exact property to ensure operation. For example, it is extremely unlikely that a 2 cm×2 cm×2 cm cube weighs more than the permitted 5 kg of a robot arm if it is not attached to another body. Therefore, an estimate of 50 g±40 g is enough for this application. However, if the robot is tasked to throw the object into a bucket in a distance, the mass would likely need to be known more accurately to compute the optimal angle and speed of the robot trajectory for throwing the cube. In this case, the robot skill would first compute the task with a physics simulation based on the available estimated parameters. The uncertainty will automatically propagate to the desired result e.g., landing the cube in the bucket. If the uncertainty is too high to achieve the target, the simulation will highlight the parameter uncertainties maximally contributing to the joint uncertainty. The autonomous system can then trade off tasks to explore the parameters actively and thus reduce the uncertainties. For example, it can lift the cube with the robot arm and compute its mass with an uncertainty given the sensory accuracy of this task. This would result in a low effort as the robot needs to grasp the cube anyways if it plans to throw it in the bucket using the robot arm. Also, it may be able to use a different sensor to measure the distance and diameter of the bucket more accurately. This task may be more effort as it may require a tool change or recording the bucket from different angles for triangulation or averaging sensing results with the target to achieve a higher accuracy. Therefore, if the mass uncertainty reduction is enough to enable the accurate throwing of the cube, the autonomous system would only execute this active refinement of its model parameter at that point. In this way, the autonomous system may continuously refine its model of the environment without requiring exhaustive manual input or exhaustive exploration of all observable parameters in the world model itself.

FIG. 4 illustrates one possible embodiment of an active learning based method 400 to design a task being performed by a robot. The task may be designed such that it includes task elements (or sub-tasks) configured to yield most observations from the real world that are correlated to one or more sensitive parameters among all the parameters contained in the parameter data layer. Block 402 of the method involves running forward simulations of the task by the physics engine by sampling parameter values from the probability distributions in the parameter data layer. Block 404 involves estimating a simulation uncertainty based on the variance in the outcomes of the forward simulations. Block 406 involves identifying one or more sensitive parameters that contribute maximally to the simulation uncertainty. In the illustrated example described above, it may be determined that varying the parameters such as thermal coefficient, conductive properties, etc. in the samples has little influence on the simulated outcomes pertaining to the task of throwing an object into a bucket. In contrast, varying the mass of the object in the samples significantly influences the simulation outcomes for this task. In the illustrative example, the mass of the object is therefore identified as a sensitive parameter. The sensitive parameter(s) may be determined based on various sensitivity analysis methods known in the art. Block 408 involves presenting a simulation scenario for the task that yields most observations correlated to sensitive parameters. This may involve trading off the original task to explore the sensitive parameters that were identified in block 406 (as described in the illustrative example). The task may be thus (re)designed based on task elements extracted from the simulation scenario.

FIG. 5 illustrates an exemplary computing environment comprising a computer system 502, within which aspects of the present disclosure may be implemented. The computing system 502 may be embodied, for example, as an industrial PC for controlling a robot of an autonomous system. Computers and computing environments, such as computer system 502 and computing environment 500, are known to those of skill in the art and thus are described briefly here.

As shown in FIG. 5, the computer system 502 may include a communication mechanism such as a system bus 504 or other communication mechanism for communicating information within the computer system 502. The computer system 502 further includes one or more processors 506 coupled with the system bus 504 for processing the information. The processors 506 may include one or more central processing units (CPUs), graphical processing units (GPUs), or any other processor known in the art.

The computer system 502 also includes a system memory 508 coupled to the system bus 504 for storing information and instructions to be executed by processors 506. The system memory 508 may include computer readable storage media in the form of volatile and/or nonvolatile memory, such as read only memory (ROM) 510 and/or random access memory (RAM) 512. The system memory RAM 512 may include other dynamic storage device(s) (e.g., dynamic RAM, static RAM, and synchronous DRAM). The system memory ROM 510 may include other static storage device(s) (e.g., programmable ROM, erasable PROM, and electrically erasable PROM). In addition, the system memory 508 may be used for storing temporary variables or other intermediate information during the execution of instructions by the processors 506. A basic input/output system 514 (BIOS) containing the basic routines that help to transfer information between elements within computer system 502, such as during start-up, may be stored in system memory ROM 510. System memory RAM 512 may contain data and/or program modules that are immediately accessible to and/or presently being operated on by the processors 506. System memory 508 may additionally include, for example, operating system 516, application programs 518, other program modules 520 and program data 522.

The computer system 502 also includes a disk controller 524 coupled to the system bus 504 to control one or more storage devices for storing information and instructions, such as a magnetic hard disk 526 and a removable media drive 528 (e.g., floppy disk drive, compact disc drive, tape drive, and/or solid state drive). The storage devices may be added to the computer system 502 using an appropriate device interface (e.g., a small computer system interface (SCSI), integrated device electronics (IDE), Universal Serial Bus (USB), or FireWire).

The computer system 502 may also include a display controller 530 coupled to the system bus 504 to control a display 532, such as a cathode ray tube (CRT) or liquid crystal display (LCD), among other, for displaying information to a computer user. The computer system 502 includes a user input interface 534 and one or more input devices, such as a keyboard 536 and a pointing device 538, for interacting with a computer user and providing information to the one or more processors 506. The pointing device 538, for example, may be a mouse, a light pen, a trackball, or a pointing stick for communicating direction information and command selections to the one or more processors 506 and for controlling cursor movement on the display 532. The display 532 may provide a touch screen interface which allows input to supplement or replace the communication of direction information and command selections by the pointing device 538.

The computing system 502 also includes an I/O adapter 546 coupled to the system bus 504 to connect the computing system 502 to a controllable physical device, such as a robot. In the example shown in FIG. 5, the I/O adapter 546 is connected to robot controller 548, which includes, for example, one or more motors for controlling linear and/or angular positions of various parts (e.g., arm, base, etc.) of the physical device or robot.

The computer system 502 may perform a portion or all of the processing steps of embodiments of the disclosure in response to the one or more processors 506 executing one or more sequences of one or more instructions contained in a memory, such as the system memory 508. Such instructions may be read into the system memory 508 from another computer readable storage medium, such as a magnetic hard disk 526 or a removable media drive 528. The magnetic hard disk 526 may contain one or more datastores and data files used by embodiments of the present disclosure. Datastore contents and data files may be encrypted to improve security. The processors 506 may also be employed in a multi-processing arrangement to execute the one or more sequences of instructions contained in system memory 508. In alternative embodiments, hard-wired circuitry may be used in place of or in combination with software instructions. Thus, embodiments are not limited to any specific combination of hardware circuitry and software.

The computer system 502 may include at least one computer readable storage medium or memory for holding instructions programmed according to embodiments of the disclosure and for containing data structures, tables, records, or other data described herein. The term “computer readable storage medium” as used herein refers to any medium that participates in providing instructions to the one or more processors 506 for execution. A computer readable storage medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 526 or removable media drive 528. Non-limiting examples of volatile media include dynamic memory, such as system memory 508. Non-limiting examples of transmission media include coaxial cables, copper wire, and fiber optics, including the wires that make up the system bus 504. Transmission media may also take the form of acoustic or light waves, such as those generated during radio wave and infrared data communications.

The computing environment 500 may further include the computer system 502 operating in a networked environment using logical connections to one or more remote computers, such as remote computing device 544. Remote computing device 544 may be a personal computer (laptop or desktop), a mobile device, a server, a router, a network PC, a peer device or other common network node, and typically includes many or all of the elements described above relative to computer system 502. When used in a networking environment, computer system 502 may include a modem 542 for establishing communications over a network 540, such as the Internet. Modem 542 may be connected to system bus 504 via network interface 545, or via another appropriate mechanism.

Network 540 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 502 and other computers (e.g., remote computing device 544). The network 540 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 540.

The embodiments of the present disclosure may be implemented with any combination of hardware and software. In addition, the embodiments of the present disclosure may be included in an article of manufacture (e.g., one or more computer program products) having, for example, a non-transitory computer-readable storage medium. The computer readable storage medium has embodied therein, for instance, computer readable program instructions for providing and facilitating the mechanisms of the embodiments of the present disclosure. The article of manufacture can be included as part of a computer system or sold separately.

The computer readable storage medium can include a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. Computer readable program instructions described herein can be downloaded to respective computing/processing devices from a computer readable storage medium or to an external computer or external storage device via a network, for example, the Internet, a local area network, a wide area network and/or a wireless network.

The system and processes of the figures are not exclusive. Other systems, processes and menus may be derived in accordance with the principles of the disclosure to accomplish the same objectives. Although this disclosure has been described with reference to particular embodiments, it is to be understood that the embodiments and variations shown and described herein are for illustration purposes only. Modifications to the current design may be implemented by those skilled in the art, without departing from the scope of the disclosure.

1. A computer-implemented method comprising:
(a) operating a controllable physical device to perform a task in a physical environment,
(b) running forward simulations of the task by a physics engine based on one or more physics parameters,
wherein the physics engine communicates with a parameter data layer in which each of the one or more physics parameters is represented as a probabilistic variable with an associated probability distribution,
wherein for each forward simulation run, a tuple of parameter values is sampled from the probability distribution of the one or more physics parameters and fed to the physics engine,
(c) obtaining an observation pertaining to the task from the physical environment and a corresponding forward simulation outcome associated with each sampled tuple of parameter values, and
(d) updating the probability distribution of the one or more physics parameters in the parameter data layer based on the observation from the physical environment and the corresponding forward simulation outcomes.

2. The method according to claim 1, wherein the one or more physics parameters comprises a plurality of correlated physics parameters, the plurality of physics parameters being modeled as a probabilistic graphical model in the parameter data layer.

3. The method according to claim 1, wherein the one or more physics parameters comprise at least one parameter that is not directly observable from the physical environment, the at least one parameter being correlated to a physical effect directly observable from the physical environment.

4. The method according to claim 1, wherein the steps (b), (c) and (d) are recursively performed over a series of discrete time steps during the performing of the step (a) based on a Bayesian filter, such that the updated probability distributions of the one or more physics parameters for a particular time step are utilized for sampling parameter values that are fed to the physics engine for running forward simulations for the next time step.

5. The method according to claim 4, wherein the Bayesian filter comprises a particle filter wherein each sampled tuple of parameter values is represented as a particle, wherein the particle filter reinforces those particles whose forward simulation outcomes are closest to the observation from the physical environment in preference to those particles whose forward simulation outcomes are farther from the observation from the physical environment.

6. The method according to claim 1, comprising modeling an initial probability distribution for each of the one or more physics parameters, wherein the initial probability distribution is a Gaussian distribution modeled around a user-specified mean value of a respective physics parameter.

7. The method according to claim 1, comprising performing a co-simulation of the physical task on a digital twin of the physical environment based on a mean value of each of the one or more physics parameters, which is obtained from the updated probability distribution of the one or more physics parameters in the parameter data layer.

8. The method according to claim 7, comprising predicting an uncertainty associated with the co-simulation of the physical task based on a variance in a current probability distribution of the one or more physics parameters in the parameter data layer.

9. The method according to claim 1, comprising designing the task being performed by the controllable physical device based on active learning, such that the task includes task elements configured to yield most observations from the physical environment that are correlated to one or more sensitive parameters among the one or more physics parameters.

10. The method according to claim 9, comprising determining the one or more sensitive parameters by:
running forward simulations of the task using sampled parameter values from the probability distribution of the one or more physics parameters in the parameter data layer,
estimating a simulation uncertainty associated with the task based on outcomes of the forward simulations, and
identifying which of the one or more physics parameters contribute maximally to the simulation uncertainty.

11. A non-transitory computer-readable storage medium including instructions that, when processed by a computer, configure the computer to perform the method according to claim 1.

12. A computing system comprising:
a processor; and
a memory storing instructions that, when executed by the processor, configure the computing system to:
(a) operate a controllable physical device to perform a task in a physical environment,
(b) run forward simulations of the task by a physics engine based on one or more physics parameters,
wherein the physics engine is configured to communicate with a parameter data layer in which each of the one or more physics parameters is represented as a probabilistic variable with. an associated probability distribution,
wherein for each forward simulation run, a tuple of parameter values is sampled from the probability distribution of the one or more physics parameters and fed to the physics engine,
(c) obtain an observation pertaining to the task from the physical environment and a corresponding forward simulation outcome associated with each sampled tuple of parameter values, and
(d) update the probability distribution of the one or more physics parameters in the parameter data layer based on the observation from the physical environment and the corresponding forward simulation outcomes.

13. The computing system according to claim 12, wherein the one or more physics parameters comprises a plurality of correlated physics parameters, the plurality of physics parameters being modeled as a probabilistic graphical model in the parameter data layer.

14. The computing system according to claim 12, wherein the one or more physics parameters comprise at least one parameter that is not directly observable from the physical environment, the at least one parameter being correlated to a physical effect directly observable from the physical environment.

15. The computing system according to claim 12, wherein the computing system is configured to recursively perform the steps (b), (c) and (d) over a series of discrete time steps during the performing of the step (a) based on a Bayesian filter, such that the updated probability distributions of the one or more physics parameters for a particular time step are utilized for sampling parameter values that are fed to the physics engine for running forward simulations for the next time step.

16. The computing system according to claim 12, wherein the computing system is configured to perform co-simulation of the physical task on a digital twin of the physical environment based on a mean value of each of the one or more physics parameters, which is obtained from the updated probability distribution of the one or more physics parameters in the parameter data layer.

17. The computing system according to claim 16, wherein the computing system is configured to predict an uncertainty associated with the co-simulation of the physical task based on a variance in a current probability distribution of the one or more physics parameters in the parameter data layer.

18. The computing system according to claim 12, wherein the computing system is configured to design the task being performed by the controllable physical device based on active learning, such that the task includes task elements configured to yield most observations from the physical environment that are correlated to one or more sensitive parameters among the one or more physics parameters.

19. The computing system according to claim 18, wherein the computing system is configured to determine the one or more sensitive parameters, for which the computing system is configured to:
run forward simulations of the task using sampled parameter values from the probability distribution of the one or more physics parameters in the parameter data layer,
estimate a simulation uncertainty associated with the task based on outcomes of the forward simulations, and
identify which of the one or more physics parameters contribute maximally to the simulation uncertainty.

20. (canceled)
